(19) United States
(12) Patent Application Publication
(10) Pub. No.: US 2007/0085207 A1
(43) Pub. Date: Apr. 19, 2007

(54) Pad structure, method of forming a pad structure, semiconductor device having a pad structure and method of manufacturing a semiconductor device

(76) Inventors: Woo-Sung Lee, Yongin-si (KR); Young-Wook Park, Suwon-si (KR); Nam-Kyu Kim, Suwon-si (KR); Bong-Hyun Kim, Bupyeong-gu (KR); Man-Sug Kang, Suwon-si (KR)

Correspondence Address: HARNESS, DICKEY & PIERCE, P.L.C., P.O. BOX 8910, RESTON, VA, 20195, US

(21) Appl. No.: 11/497,279

(22) Filed: Aug. 2, 2006

(30) Foreign Application Priority Data
Aug. 2, 2005 (KR) 10-2005-0070498

(51) Int. Cl. H01L 21/44; H01L 23/48; H01L 23/52; H01L 29/40; H01L 21/4763

(52) U.S. Cl. 257/739; 438/618

(57) ABSTRACT

A pad structure, a method of forming a pad structure, a semiconductor device having a pad structure and a method of manufacturing a semiconductor device are disclosed. The pad structure may include a first pad, a second pad, a third pad and/or a spacer. The first pad may contact a contact region on a substrate. The first pad may include doped polysilicon. The second pad may contact the first pad. The second pad may include a metal silicide or a metal silicongermanium. The third pad may contact the second pad. The third pad may include a conductive material (e.g., doped polysilicon, a metal or a metal nitride). The spacer may be formed on sidewalls of the second and the third pads.

### PRIORITY STATEMENT

This application claims the benefit of priority under 35 USC § 119 to Korean Patent Application No. 2005-70498, filed on Aug. 2, 2005, in the Korean Intellectual Property Office, the contents of which are herein incorporated by references in its entirety.

### BACKGROUND OF THE INVENTION

1. Field of the Invention

Example embodiments of the present invention relate to a pad structure, a method of forming a pad structure, a semiconductor device having a pad structure and a method of manufacturing a semiconductor device. Other example embodiments of the present invention relate to a pad structure having increased characteristics, a method of forming a pad structure, a semiconductor device having a pad structure with increased characteristics and a method of manufacturing a semiconductor device.

2. Description of the Related Art

In a rapidly developing information society, highly integrated semiconductor devices having more rapid data transfer rates are desirous in order to process data faster. However, a line width of a gate electrode and an impurity region (e.g., a source region or a drain region) may decrease as the semiconductor device becomes more highly integrated. The desire to secure more stable electrical connections may increase as the significance of design rule decreases.

When a conventional polysilicon layer is formed on a contact area of a highly integrated semiconductor device, an electrical resistance (e.g., contact resistance or sheet resistance) may increase such that it may be difficult to increase an operating speed of the semiconductor device. A power consumption for operating the semiconductor device may substantially increase. As such, a metal silicide (MSi₂) layer may be formed on pad regions in order to decrease the contact resistance or the sheet resistance, increasing conductivity of the contact in the semiconductor device. The metal silicide layer, for example, may include tungsten silicide, titanium silicide, cobalt silicate or the like. Due to the lower electrical resistance, lower silicon consumption, higher thermal stability and/or higher chemical stability, the metal silicide layer may be more suitable for use in a highly integrated semiconductor device.

In a silicidation process for forming the metal silicide layer, a metal (e.g., titanium (Ti), nickel (Ni) or cobalt (Co)) may be deposited on an underlying layer by a chemical vapor deposition (CVD) process to form a metal layer on the underlying layer. A heat treatment may be performed on the metal layer. Silicon (Si) in the underlying layer may be reacted with metal in the metal layer to form a metal silicide layer (e.g., titanium silicate, nickel silicate, cobalt silicate, etc.) on the underlying layer.

When the metal silicide layer is formed, agglomeration may occur. Due to agglomeration, a portion of the metal silicide layer may be damaged and another portion of the metal silicide layer may be formed more excessively (e.g., thicker than desired). In order to ensure more stable contact resistances, the metal silicide layer may be formed having a desired thickness. When the metal silicide layer is formed more excessively, distances between adjacent pads may decrease. Thus, highly integrated semiconductor devices may experience an electrical short between the pads, thereby electrical characteristics of the semiconductor devices may deteriorate.

Examples of a method of forming a transistor including a metal silicide are acknowledged by the prior art.

FIGS. 1A to 1D are diagrams illustrating cross-sectional views of a conventional method of forming a pad.

Referring to FIG. 1A, a lower structure 15 may be formed on, or in, a substrate 10. The lower structure 15 may include a transistor. The transistor may include a gate structure and source/drain regions formed on a sidewall of the gate structure. A first insulation interlayer 20 may be formed on the substrate 10 to cover the lower structure 15. A contact 25 may formed in the first insulation interlayer 20. The contact 25 may contact the source/drain region of the substrate 10. The contact 25, for example, may be formed of polysilicon.

Referring to FIG. 1B, a second insulation interlayer 30 may he formed on the contact 25 and the first insulation interlayer 20. The second insulation interlayer 30 may be partially etched to form an opening 35 exposing the contact 25.

A spacer 40 may be formed on a sidewall of the opening 35. The spacer 40 may be formed of a nitride (e.g., silicon nitride).

Referring to FIG. 1C, a metal layer 45 may be formed on the exposed contact 25, the second insulation interlayer 30 and a sidewall of the opening 35 having the spacer 40. The metal layer 45 may be formed using titanium, cobalt, tungsten or the like.

Referring to FIG. 1D, in a thermal treatment process, the metal layer 45 may react with silicon atoms in the contact 25. For example, a silicidation reaction may be performed between polysilicon in the contact 25 and the metal layer 45 on the contact 25 to form a metal silicide layer 50. A conductive layer 55 may be formed on the metal silicide layer 50. A pad 60 including the metal silicide layer 50, the conductive layer 55 and/or the spacer 40 may be formed.

In the silicidation reaction between the polysilicon in the contact 25 and the metal layer 45, the metal silicide layer 50 may be formed thicker than desired due to agglomeration from the silicidation reaction. When the metal silicide layer 50 is formed an undesirable height from the contact 25, an electrical short may occur between adjacent contacts. As a design rule of the semiconductor device decreases, an alignment margin in manufacturing the semiconductor device may decrease. As a result, an electrical short may occur between adjacent contacts.

### SUMMARY OF THE INVENTION

Example embodiments of the present invention relate to a pad structure, a method of forming a pad structure, a semiconductor device having a pad structure and a method of manufacturing a semiconductor device.

Example embodiments of the present invention provide a pad structure having increased characteristics. Other example embodiments of the present invention provide a method of forming a pad structure having increased characteristics.

Example embodiments of the present invention provide a semiconductor device including a pad structure having increased characteristics. Other example embodiments of the present invention provide a method of manufacturing a semiconductor device including a pad structure having increased characteristics.

According to example embodiments of the present invention, there is provided a pad structure. The pad structure may include a first pad including silicon, a second pad formed on the first pad and including a metal silicide or a metal silicongermanium and/or a third pad formed on the second pad and including a conductive material.

In example embodiments of the present invention, the second pad may further include a selective epitaxial growth (SEG) layer derived from the first pad. The second pad may include titanium silicide, cobalt silicide, tungsten silicide, nickel silicide, titanium silicongermanium, cobalt silicongermanium, tungsten silicongermanium, nickel silicongermanium or a combination thereof.

In other example embodiments of the present invention, the metal silicide or the silicongermanium in the second pad may be formed by a silicidation process of the SEG layer.

In an example embodiment of the present invention, a spacer may be formed on sidewalls of the second pad and the third pad. A bottom surface of the spacer may be formed on or contacting the first pad.

In an example embodiment of the present invention, the first pad may have a first dimension. The second and third pads may have a second dimension smaller than the first dimension. The entire second and third pads may have a second dimension smaller than the first dimension.

According to other example embodiments of the present invention, there is provided a method of forming a pad structure. In the method, a first pad including silicon may be formed. A second pad may be formed on the first pad. The second pad may be formed of metal silicide or metal silicongermanium. A third pad may be formed on the second pad.

In example embodiments of the present invention, an insulation layer may be formed on the first pad. An opening, exposing the first pad, may be formed through the insulation layer. A preliminary second pad, partially filling the opening, may be formed on the first pad. A metal layer may be formed on the preliminary second pad. A thermal treatment process may be performed on the preliminary second pad and the metal layer to from the second pad.

In example embodiments of the present invention, the preliminary second pad may further include a SEG layer derived from the first pad by performing a SEG process. In example embodiments of the present invention, the SEG layer formed on the insulation layer may be removed.

In example embodiments of the present invention, a cleaning process may be performed prior to performing the SEG process. The cleaning process may be performed using a hydrogen plasma.

In other example embodiments of the present invention, the metal layer may include titanium, cobalt, tungsten, nickel or a combination thereof.

According to example embodiments of the present invention, a first rapid thermal treatment process may be performed on the preliminary second pad and the metal layer to form a preliminary metal silicide layer or a preliminary metal silicongermanium layer. An unreacted metal layer may be removed. A second rapid thermal treatment process may be performed on the preliminary metal silicide layer or the preliminary metal silicongermanium layer to form the second pad.

In example embodiments of the present invention, the first rapid thermal treatment process may be performed at a temperature of about 450° C. to about 650° C. The second rapid thermal treatment process may be performed at a temperature of about 750° C. to about 950° C.

According to example embodiments of the present invention, a spacer may be formed on sidewalls of the second pad and the third pad.

According to still other example embodiments of the present invention, there is provided a semiconductor device. The semiconductor device may include a substrate including a contact region, a first insulation interlayer formed on the substrate, a first pad formed of silicon in the first insulation interlayer and electrically connected to the contact region, a second insulation interlayer having an opening formed on the first pad and the first insulation interlayer, a second pad formed on the first pad and partially filling the opening and/or a third pad formed on the second pad and filling the opening. The opening may be formed through the second insulation interlayer, exposing the first pad. The second pad may include a metal silicate or a metal silicongermanium.

In example embodiments of the present invention, the second pad may further a SEG layer derived from the first pad.

In example embodiment of the present invention, the metal silicide or the metal silicongermanium in the second pad may be formed by a silicidation process of the SEG layer.

According to still other example embodiments of the present invention, there is provided a method of manufacturing a semiconductor device. In the method, a contact region may be formed on a substrate. A first insulation interlayer may also be formed on the substrate. A first pad, including silicon and electrically connected to the contact region, may be formed in the first insulation interlayer. A second insulation interlayer may be formed on the first pad and the first insulation interlayer. An opening exposing the first pad may be formed. A preliminary second pad partially filling the opening may be formed on the first pad. A metal layer may be formed on the preliminary second pad and the second insulation interlayer. A thermal treatment process may be performed on the preliminary second pad and the metal layer to form a second pad including a metal silicide and a metal silicongermanium. A third pad filling the opening may be formed on the second pad.

In other example embodiments of the present invention, the preliminary second pad may further include a SEG layer derived from the first pad by performing a SEG process.

In example embodiments of the present invention, the SEG layer formed on the second insulation interlayer may be removed.

According to other example embodiments of the present invention, in forming a metal silicide layer or a metal silicongermanium layer for decreasing a contact resistance, a silicon layer or a silicon germanium layer may be formed by a selective epitaxial growth (SEG) process on a region where the metal silicide layer or the metal silicongermanium layer is formed. The silicon layer or silicon germanium layer may be formed by performing a silicidation reaction. The likelihood of excessive agglomeration occurring due to the formation of the metal silicide or the metal silicongermanium may decrease. As such, the likelihood of an electrical short occurring between adjacent pads due to more excessive agglomeration may decrease.

### BRIEF DESCRIPTION OF THE DRAWINGS

Example embodiments of the present invention will be more clearly understood from the following detailed description taken in conjunction with the accompanying drawings. FIGS. 1-5 represent non-limiting, example embodiments of the present invention as described herein.

FIGS. 1A to 1D are diagrams illustrating cross-sectional views of a conventional of forming a pad;

FIG. 2 is a diagram illustrating a cross-sectional view of a pad structure in accordance with example embodiments of the present invention;

FIGS. 3A to 3F are diagrams illustrating cross-sectional views of a method of forming a pad structure in accordance with example embodiments of the present invention;

FIG. 4 is a diagram illustrating a cross-sectional view of a method of manufacturing a semiconductor device in accordance with example embodiments of the present invention; present invention.

FIGS. 5A to 5F are diagrams illustrating cross-sectional views of a method of manufacturing a semiconductor device in accordance with example embodiments of the present invention.

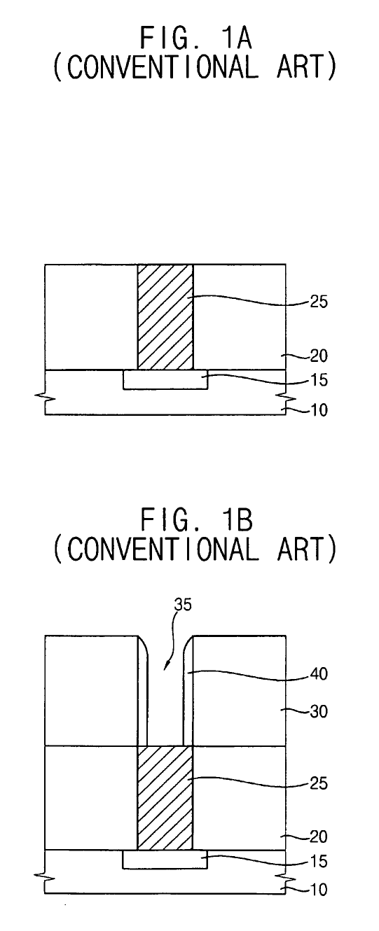

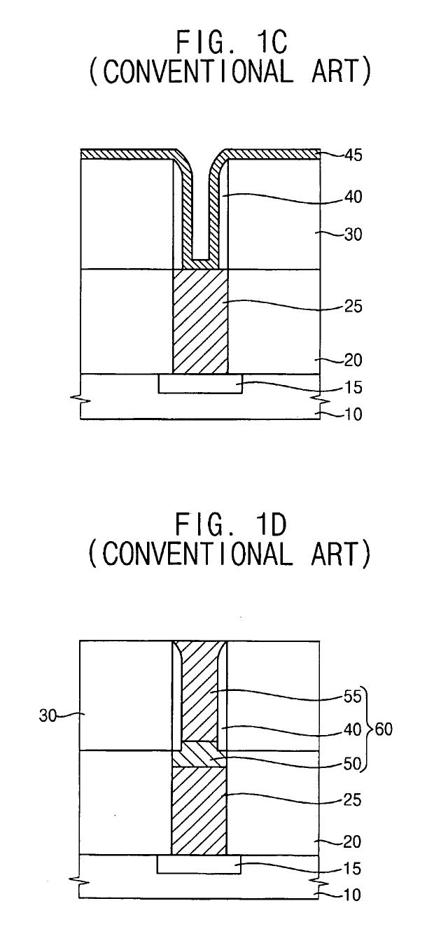

### DESCRIPTION OF EXAMPLE EMBODIMENTS

Various example embodiments of the present invention will now be described more fully with reference to the accompanying drawings in which some example embodiments of the invention are shown. In the drawings, the thicknesses of layers and regions may be exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one clement from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for case of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but arc to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Also, the use of the words “compound,” “compounds,” or “compound(s),” refer to either a single compound or to a plurality of compounds. These words arc used to denote one or more compounds but may also just indicate a single compound.

Unless otherwise defined, all terms (including technical and scientific terms) used herein have the same meaning as commonly understood by one of ordinary skill in the art lo which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments of the present invention, various aspects of the present invention will be described in detail with reference to the attached drawings. However, the present invention is not limited to the example embodiments described.

Example embodiments of the present invention relate to a pad structure, a method of forming a pad structure, a semiconductor device having a pad structure and a method of manufacturing a semiconductor device. Other example embodiments of the present invention relate to a pad structure having increased characteristics, a method of forming a pad structure, a semiconductor device having a pad structure with increased characteristics and a method of manufacturing a semiconductor device.

A pad structure and a method of forming the same will be described.

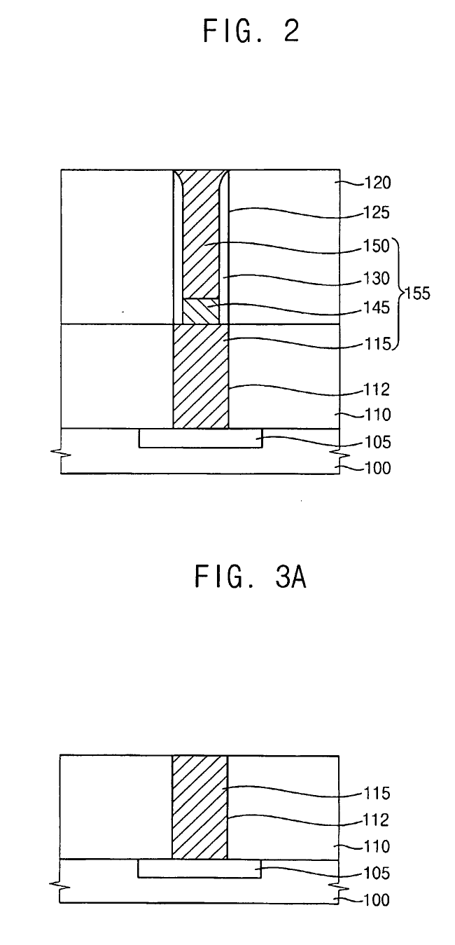

FIG. 2 is a diagram illustrating a cross-sectional view of a pad structure in accordance with example embodiments of the present invention.

Referring to FIG. 2, a pad structure 155 may include a first pad 115, a second pad 145, a third pad 150 and/or a spacer 130.

The first pad 115 may contact a conductive structure (e.g., a contact region) on a substrate 100. The first pad 115 may be formed of polysilicon. The second pad 145 may be formed on the first pad 115. The second pad 145 may include a metal silicide or a metal silicongermanium. The third pad 150 may be formed on the second pad 145. The third pad 150 may include a conductive material (e.g., doped polysilicon, a metal or a metal nitride). A spacer 130 may be formed on sidewalls of the second pad 145 and the third pad 150. A bottom surface of the spacer 130 may contact the first pad 115.

The pad structure 155 may be formed on the substrate 100 (e.g., a silicon wafer or a silicon on insulator (SOI)). The substrate 100 may include a lower structure 105. The lower structure 105 may include a contact region, a pad, a conductive pattern, a gate structure, a wiring, a transistor, etc.

A first insulation layer 110 may be formed on the substrate 100 to cover the lower structure 105. The first insulation layer 110 may include an oxide. For example, the first insulation layer 110 may include phosphor silicate glass (PSG), boro-phosphor silicate glass (BPSG), undoped silicate glass (USG), spin on glass (SOG), tetra ethyl ortho silicate (TEOS), plasma enhanced-TEOS (PE-TEOS), flowable oxide (FOX), high density plasma-chemical vapor deposition (HDP-CVD) oxide, etc.

A first opening 112 may be formed through the first insulation layer 110. The first opening 112 may expose the lower structure 105. The first pad 115 may fill the first opening 112 and contact the lower structure 105. In other example embodiments of the present invention, the first pad 115 may include polysilicon. The first pad 115 may be formed between the second pad 145 and the lower structure 105. The first pad 115 may electrically connect the second pad 145 with the lower structure 105.

A second insulation layer 120 may formed on the first pad 115 and the first insulation layer 110. The second insulation layer 120 may include an oxide (e.g., BPSG, PSG, PE-TEOS, USG, FOX, SOG, HDP-CVD oxide, etc.). In example embodiments of the present invention, the second insulation layer 120 may include an oxide substantially the same as an oxide of the first insulation layer 110. In other example embodiments of the present invention, the second insulation layer 120 may include an oxide substantially different from an oxide of the first insulation layer 110.

A second opening 125, exposing a portion of the first pad 115, may be formed in the second insulation layer 120. The second pad 145 and the third pad 150, filling the second opening 125, may be formed on the first pad 115 and the first insulation layer 110. In example embodiments of the present invention, the second opening 125 may have a dimension substantially the same as the first opening 115. In other example embodiments of the present invention, the second opening 125 may have a greater dimension than the first opening 112. In yet other example embodiments of the present invention, the second opening 125 may have a smaller dimension than the first opening 112.

The spacer 130 may be formed on sidewalls of the second pad 145 and the third pad 150. The spacer 130 may include a material having an etching selectivity relative to an etching selectivity of the second insulation layer 120. For example, the spacer 130 may include a nitride (e.g, silicon nitride) or an oxynitride (e.g., silicon oxynitride). In other example embodiments of the present invention, the spacer 130 may not be formed on the sidewalls of the second pad 145 and the third pad 150.

The second pad 145 and the third pad 150 together may pass through the second insulation layer 120. The second pad 145 may contact the first pad 115. The second pad 145 may include a metal silicide or a metal silicongermanium. Examples of the metal silicide or the metal silicongermanium may include titanium silicide, cobalt silicide, tungsten silicide, nickel silicide, titanium silicongermanium, cobalt silicongermanium, tungsten silicongermanium, nickel silicongermanium, etc. In example embodiments of the present invention, the second pad 145 may further include a selective epitaxial growth (SEG) layer derived from the first pad 115. The second pad 145 may further include the SEG layer derived from the first pad 115 by a SEG process. At least a portion of the SEG layer may be formed into a metal silicide layer or a metal silicongermanium layer by a silicidation process. In yet other example embodiments of the present invention, the second pad 145 may have a single layer structure including the metal silicide layer or the metal silicongermanium layer. The second pad 145 may have a multi layer structure including the metal silicide layer or the metal silicongermanium layer. The multi layer structure may also include the SEG layer formed on the metal silicide layer or the metal silicongermanium layer.

The third pad 150 may include polysilicon, a metal or a conductive metal nitride. For example, the third pad 150 may include tungsten, titanium, tantalum, aluminum, copper, tungsten nitride, titanium nitride, tantalum nitride, aluminum nitride, etc.

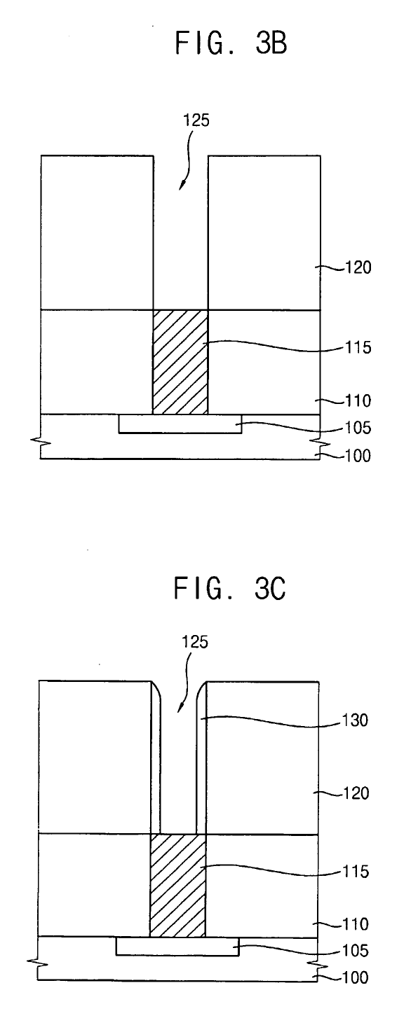

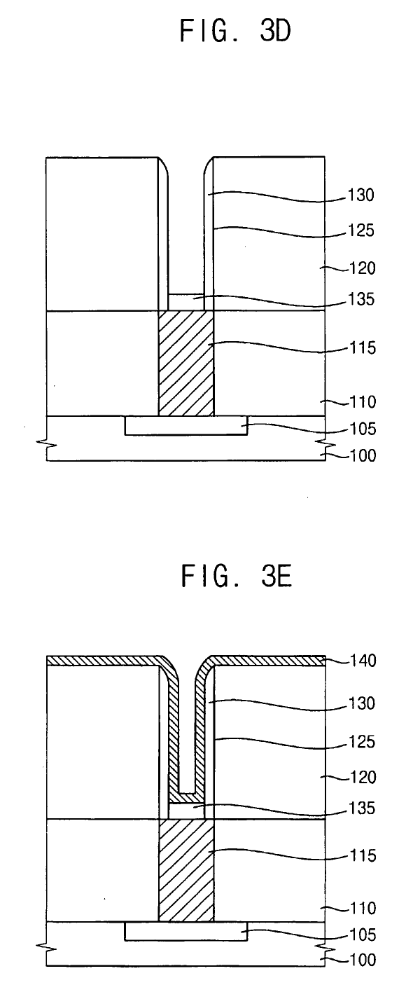

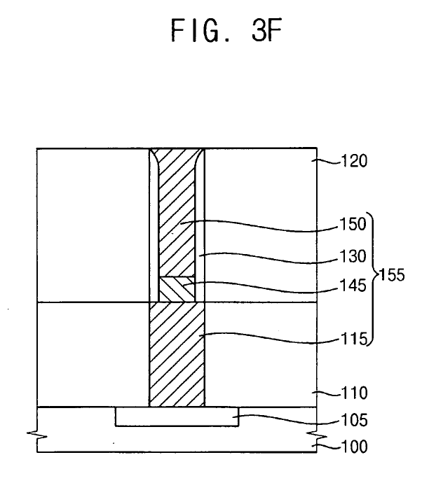

FIGS. 3A to 3F are diagrams illustrating cross-sectional views of a method of forming a pad structure in accordance with example embodiments of the present invention.

Referring to FIG. 3A, a lower structure 105 may be formed on a substrate 100 (e.g., a silicon wafer or a SOI substrate). The lower structure 105 may include a contact region, a pad, a conductive pattern, a gate structure, a wiring, a transistor and/or the like. The contact region, the pad, the conductive pattern, the gate structure, the wiring, the transistor and/or the like may be formed on the substrate 100.

A first insulation layer 110 may be formed on the substrate 100, covering the lower structure 105. The first insulation layer 110 may be formed using an oxide (e.g., BPSG, PSG, USG, SOG, FOX, PE-TEOS, HDP-CVD oxide, etc.). The first insulation layer 110 may be formed by a deposition process (e.g., a chemical vapor deposition (CVD) process, a plasma enhanced-CVD (PE-CVD) process, an atomic layer deposition (ALD) process, a high density plasma-CVD (HDP-CVD) process, etc.). In other example embodiments of the present invention, the first insulation layer 110 may be planarized by a chemical mechanical polishing (CMP) process, an etch-back process or a combination process of CMP and etch-back.

A first photoresist film (not shown) may be formed on the first insulation layer 110. The first photoresist film may be exposed to light and developed, forming a first photoresist pattern on the first insulation layer 110. The first insulation layer 110 may be partially etched using the first photoresist pattern as an etching mask to form a first opening 112. The first opening 112 may partially expose the lower structure 105 formed on the substrate 100.

The first photoresist pattern may be removed by an ashing process and/or a stripping process. A first conductive layer may be formed on the first insulation layer 110 to fill the first opening 112. In other example embodiments of the present invention, the first conductive layer may be formed using polysilicon. The first conductive layer may be formed by a CVD process, an ALD process, a HDP-CVD process, etc.

The first conductive layer may be partially removed to expose the first insulation layer 110. The first conductive layer may be removed by a chemical mechanical polishing (CMP) process, an etch-back process, or a combination process of CMP and etch-back. The first pad 115, filling the first opening 112, may be formed.

Referring to FIG. 3B, a second insulation layer 120 may be formed on the first pad 115 and the first insulation layer 110. The second insulation layer 120 may be formed by a CVD process, a PE-CVD process, an ALD process, an HDP-CVD process, etc. The second insulation layer 120 may be formed using an oxide (e.g, BPSG, PSG, USG, SOG, FOX, PE-TEOS. HDP-CVD oxide, etc.). In example embodiments of the present invention, the second insulation layer 120 may be formed using an oxide substantially the same as the first insulation layer 110. In example embodiments of the present invention, the second insulation layer 120 may be formed using an oxide substantially different from the first insulation layer 110.

A second photoresist film (not shown) may be formed on the second insulation layer 120. The second photoresist film may be exposed to light and developed to form a second photoresist pattern on the second insulation layer 120. The second insulation layer 120 may be partially etched using the second photoresist pattern as an etching mask to form a second opening 125 in the second insulation layer 120. The second opening 125 may expose the first pad 115. The second photoresist pattern may be removed by an ashing process and/or a stripping process.

The second opening 125 may expose a surface of the first pad 115. In example embodiments of the present invention, the second opening 125 may be formed having a dimension substantially the same as the first opening 112. In other example embodiments of the present invention, the second opening 125 may be formed having a greater dimension than the first opening 112. In still other example embodiments of the present invention, the second opening 125 may be formed having a smaller dimension than the first opening 112.

Referring to FIG. 3C, a third insulation layer (not shown) may be conformably formed, or form-fitted, on the exposed first pad 115 and the second insulation layer 120. The third insulation layer may be anisotropically etched to form a spacer 130 on a sidewall of the second opening 125. The spacer 130 may be formed with a material having an etching selectivity relative to an etching selectivity of the second insulation layer 120. For example, the spacer 130 may be formed using a nitride (e.g., silicon nitride) or an oxynitride (e.g., silicon oxynitride).

Referring to FIG. 3D, a preliminary second pad 135 may be formed on the first pad 115. The preliminary second pad 135 may be formed filling a portion of the second opening 125 such that the preliminary second pad 135 has a desired height from the first pad 115. The preliminary second pad 135 may not fill the second opening 125.

In example embodiments of the present invention, the preliminary second pad 135 may be formed by a selective epitaxial growth (SEG) process from the first pad 115. The SEG process may include forming a layer by depositing atoms on a lower layer along a crystal face or depositing atoms in a crystal direction of the lower layer. The SEG process may be performed by a low pressure chemical vapor deposition (LPCVD) process, an ultra high vacuum chemical vapor deposition (UHVCVD) process, etc.

In example embodiments of the present invention, the preliminary second pad 135 may be formed by growing silicon according to the SEG process wherein the LPCVD process is performed. In the SEG process using the LPCVD process, a dichlorosilane (SiCl₂H₂) gas and a hydrogen chloride (HCl) gas may be used as a reactant gas. A hydrogen (H₂) gas may be used as a carrier gas.

In other example embodiments of the present invention, the preliminary second pad 135 may be formed by growing silicon in accordance with the SEG process using the UHVCVD process. In the SEG process using the UHVCVD process, a silane (SiH₄) gas, a disilane (Si₂H₆) gas or a dichlorosilane (SiCl₂H₂) gas may be used as a reactant gas. The UHVCVD process may be performed at a lower temperature relative to a process temperature of the LPCVD process.

In still other example embodiments of the present invention, the preliminary second pad 135 may be formed by growing silicongermanium according to the SEG process. For example, a silicongermanium layer may be derived from the first pad 115 using a source gas including dichlorosilane (SiCl₂H₂) gas, a germane (GeH₄) gas or a hydrogen chloride (HCl) gas. The SEG process may be performed at a temperature of about 700° C. to about 900° C. under a pressure of about 1 torr to about 100 torr.

In the SEG method, the silicon layer or the silicongermanium layer may be formed on the second insulation layer 120 by an undesirable epitaxial growth. The silicon layer or the silicongermanium layer on the second insulation layer 120 may be removed, leaving the silicon layer or the silicongermanium layer on the first pad 115. In other example embodiments of the present invention, the silicon layer or the silicongermanium layer on the second insulation layer 120 may be removed by an anisotropic etching process. In the anisotropic etching process, the preliminary second pad 135 on the first pad 115 may be also removed such that a height of the preliminary second pad 135 may be insufficient to form metal silicide or metal silicongermanium. In yet other example embodiments of the present invention, the SEG process and the anisotropic etching process may be repeated at least once. The silicon layer or the silicongermanium layer may not be formed on the second insulation layer 120. The preliminary second pad 135 having a certain height may be formed on the first pad 115.

According to example embodiments of the present invention, a cleaning process may be performed prior to forming the preliminary second pad 135. The cleaning process may remove a native oxide layer formed on a surface on the first pad 115, and any etching damage occurred during a formation of the second opening 125. When the SEG process is performed after the cleaning process, the silicon layer or the silicongermanium layer may be more uniformly formed on the first pad 115. In example embodiments of the present invention, the cleaning process may include a wet cleaning process using an etching solution including hydrogen fluoride. The cleaning process may include a dry etching process. The cleaning process may also include a hydrogen baking process. In other example embodiments of the present invention, the cleaning process may include a plasma native oxide cleaning (PNC) process using a hydrogen plasma, a nitrogen plasma or a combination of hydrogen plasma and nitrogen plasma. An inert gas may be further used in the PNC process.

Referring to FIG. 3E, a metal layer 140 may be formed on the preliminary second pad 135 and the second insulation layer 120. The metal layer 140 may he formed using titanium, cobalt, aluminum, tungsten, nickel, etc. In addition, the metal layer 140 may be formed by a CVD process, a PVD process, an ALD process, etc. In example embodiments of the present invention, the metal layer 140 may be formed by a CVD process using titanium. A thickness of the metal layer 140 may be controlled by the preliminary second pad 135 consumed in a subsequent silicidation process. The metal silicide layer or the metal silicongermanium layer formed by a silicidation reaction between the metal layer 140 and the preliminary second pad 135. The metal layer 140 may be formed having a desired thickness such that the metal suicide layer or the metal silicongermanium layer does not permeate the first pad 115.

In example embodiments of the present invention, a barrier layer may be formed on the metal layer 140. The barrier layer may prevent, or retard, the metal layer 140 from oxidizing natively in a thermal process for forming a metal silicide layer or a metal silicongermanium layer. The barrier layer may be formed using a metal nitride (e.g., titanium nitride, titanium aluminum nitride, etc.).

A first rapid thermal process may be performed to induce a reaction between the preliminary second pad 135 and the metal layer 140. The first rapid thermal process may be performed at a temperature of about 450° C. and 650° C. A preliminary metal silicide layer or a preliminary metal silicongermanium layer may be formed. Because the second insulation layer 120 and the spacer 130 do not include silicon or silicongermanium, the second insulation layer 120 and the spacer 130 may not be reacted with the metal layer 140 in the first rapid thermal process. An unreacted metal layer 140 may be removed.

A second rapid thermal process may be necessary to form the preliminary metal silicide layer or the preliminary metal silicongermanium layer. The second rapid thermal process may be performed at a temperature of about 750° C. to about 950° C. By the second rapid thermal process, the preliminary metal silicide layer may be formed into a metal silicide layer. The preliminary metal silicongermanium layer may be altered to a metal silicongermanium layer. A second pad 145 may be formed on the first pad 115. The second pad 145 includes a metal silicide or a metal silicongermanium.

In example embodiments of the present invention, the preliminary second pad 135 may be reacted with the metal layer 140. Substantially all of the preliminary second pad 135, or a portion thereof, may be reacted with the metal layer 140. The second pad 145 may be formed in a single layer structure including the metal silicide layer or the metal silicongermanium layer. In other example embodiments of the present invention, a first portion of the preliminary second pad 135 may be reacted with the metal layer 140. A second portion of the preliminary second pad 135 may not be reacted with the metal layer 140. Because the preliminary second pad 135 may be formed by the SEG process, the preliminary second pad 135 may have a desired height from the first pad 115. The metal silicide or the metal silicongermanium in the second pad 145 may not penetrate the first pad 115. The likelihood of excessive agglomeration occurring due to the metal silicide or the metal silicongermanium may decrease.

Referring to FIG. 3F, a second conductive layer may be formed to completely, or substantially, fill the second opening 125. The second conductive layer may be formed using polysilicon, a metal, a conductive metal nitride, etc. For example, the second conductive layer may be formed using tungsten, titanium, tantalum, aluminum, copper, tungsten nitride, titanium nitride, tantalum nitride, aluminum nitride, etc. The second conductive layer may be formed by a sputtering process, a CVD process, an ALD process, a PLD process, etc.

The second conductive layer may be partially removed by a CMP process, an etch-back process or a combination of CMP and etch-back to expose the second insulation layer 120 in order to form a third pad 150. A pad structure 155 including the first pad 115, the second pad 145, the third pad 150 and the spacer 130 may be formed. The first pad 115 may contact the contact region of the substrate 200. The first pad 115 may include polysilicon. The second pad 145 may contact the first pad 115. The second pad 145 may include the metal silicide or the metal silicongermanium. In other example embodiments of the present invention, the second pad 145 may further include the SEG layer derived from the first pad 115. The third pad 150 may contact the second pad 145. The third pad 150 may include polysilicon, a metal, a conductive metal nitride, etc. The spacer 130 may be formed on sidewalls of the second pad 145 and the third pad 150. A bottom surface of the third pad 150 may contact the first pad 115.

A semiconductor device and method of manufacturing the same will now be described.

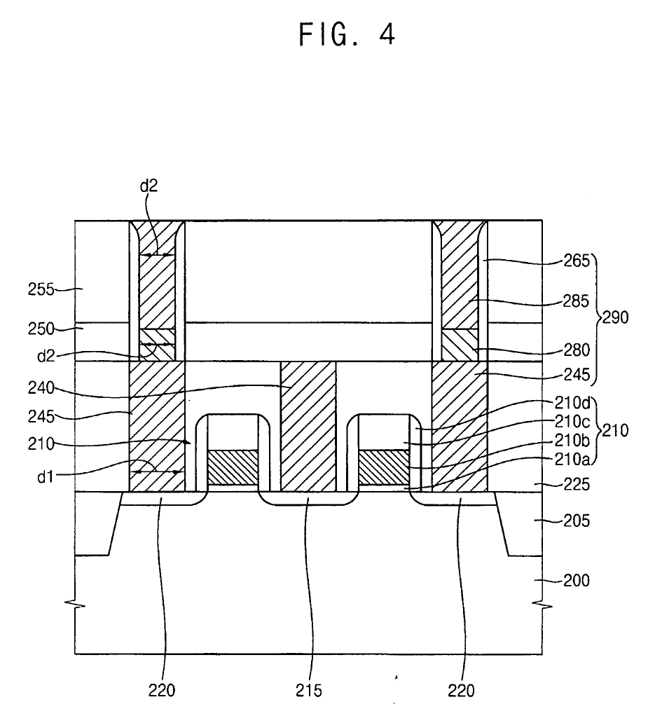

FIG. 4 is a diagram illustrating a cross-sectional view of a method of manufacturing semiconductor device in accordance with example embodiments of the present invention.

Referring to FIG. 4, the semiconductor device may include a substrate 200 including a transistor structure thereon, a first insulation interlayer 225, a first pad 240, a second pad 245, a second insulation interlayer 250, a third insulation interlayer 255 and/or a pad structure 290.

The transistor structure may include a first contact region 215, a second contact region 220 and/or a gate structure 210 formed on the substrate 200.

The gate structure 210 may include a gate oxidation layer pattern 210a, a gate conductive layer pattern 210b, a gate mask pattern 210c and/or a gate spacer 210d. The gate structure 210 may be electrically insulated from the adjacent gate structure 210 by the gate spacer 210d formed on a sidewall of the gate structure 210.

The first contact region 215 and the second contact region 220 may be formed on an upper portion of the substrate 200. The first and the second contact regions 215 and 220 may correspond to source/drain regions. The transistor structure including the first contact region 215, the second contact region 220 and/or the gate structure 210 may be formed on the substrate 200.

The first insulation interlayer 225 may be formed on the substrate, covering the transistor structure. The first insulation interlayer 225 may include an oxide (e.g., BPSG, PSG, PE-TEOS, USG, FOX, SOG, HDP-CVD oxide, etc.).

The first pad 240 and the second pad 245 may be formed through the first insulation interlayer 225. The first pad 240 may contact the first contact region 215 of the substrate 200. The second pad 245 may contact the second contact region 220 of the substrate 200. The first pad 240 and the second pad 245 may include polysilicon.

The second insulation interlayer 250 may be formed on the first insulation interlayer 225. The second insulation interlayer 250 may electrically insulate the first pad 250 with a bit line (not shown) formed on the second insulation interlayer 250. The second insulation interlayer 250 may include an oxide (e.g., BPSG, PSG, PE-TEOS, USG, FOX, SOG, HDP-CVD oxide, etc.). The second insulation interlayer 250 may include an oxide substantially the same as the first insulation interlayer 225. In example embodiments of the present invention, the second insulation interlayer 250 may include an oxide substantially different from the first insulation interlayer 225.

The third insulation interlayer 255 may be formed on the second insulation interlayer 225. The third insulation interlayer 255 may include an oxide (e.g., BPSG, PSG, PE-TEOS, USG, FOX, SOG, HDP-CVD oxide, etc.). The third insulation interlayer 255 may include an oxide substantially the same as the second insulation interlayer 250. The third insulation interlayer 255 may include an oxide substantially different from the second insulation interlayer 250.

A third pad 290 and a fourth pad 285 together may pass through the third insulation interlayer 255 and the second insulation interlayer 250. The third pad 280 may contact the second pad 245. A spacer 265 may be formed on the sidewalls of the third pad 280 and the fourth pad 285. The spacer 265 may include a material having an etching selectivity relative to an etching selectivity of the third insulation interlayer 255. For example, the spacer 255 may include a nitride (e.g., silicon nitride).

In example embodiments of the present invention, the third pad 280 may include a metal silicide or a metal silicongermanium. Examples of the metal silicide or the metal silicongermanium may include titanium silicide, cobalt silicide, tungsten silicide, nickel silicide, titanium silicongermanium, cobalt silicongermanium, tungsten silicongermanium, nickel silicongermanium, etc. The third pad 280 may further include a SEG layer derived from the second pad 245.

The fourth pad 285 may include a conductive material (e.g., polysilicon, a metal or a conductive metal nitride. For example, the fourth pad 285 may include tungsten, titanium, tantalum, aluminum, copper, tungsten nitride, titanium nitride, tantalum nitride, aluminum nitride. etc.

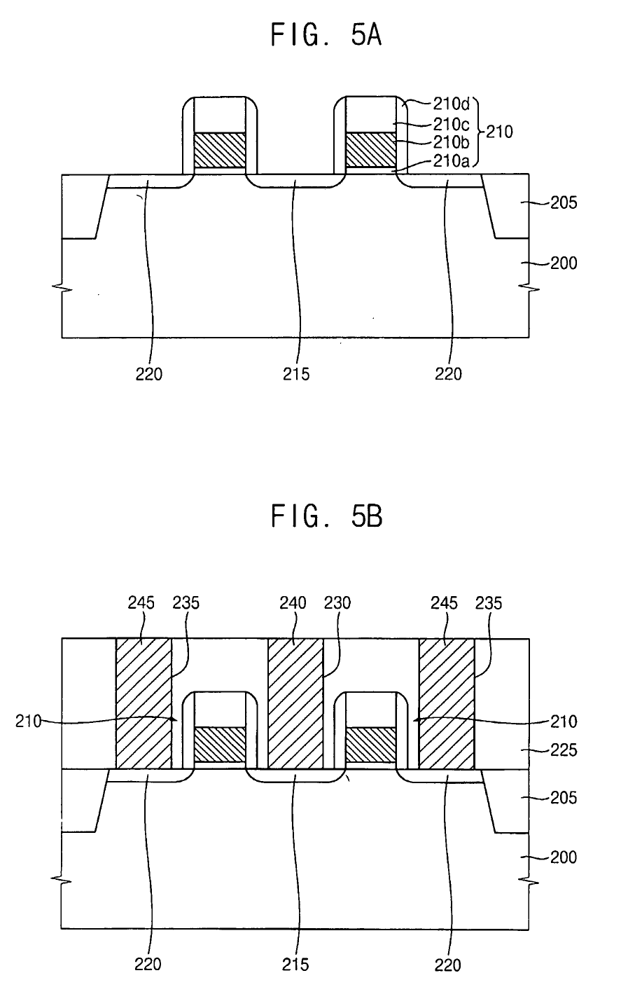

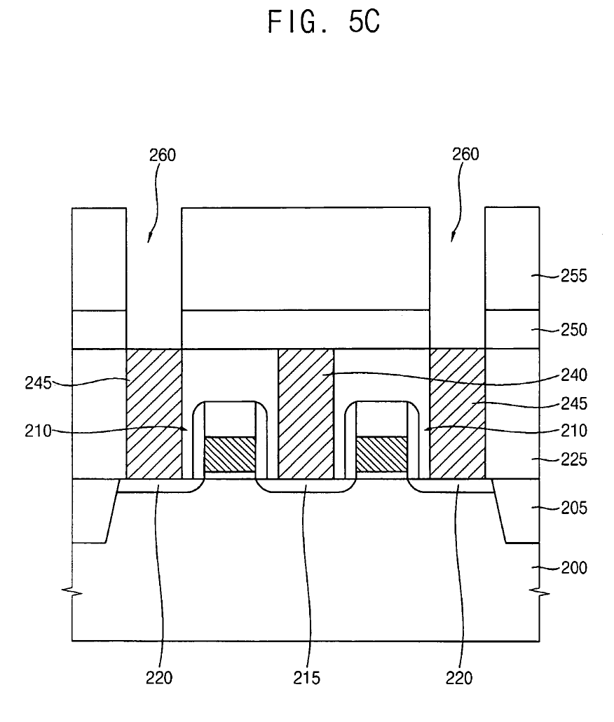

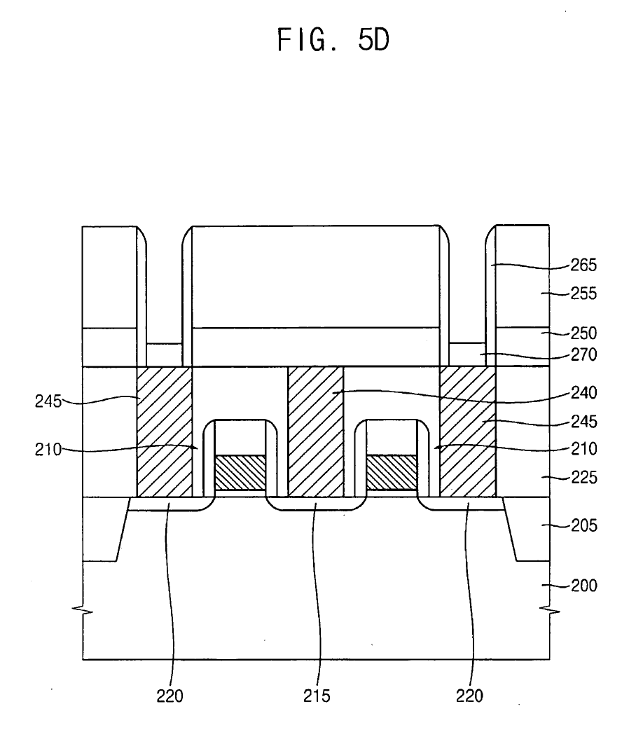

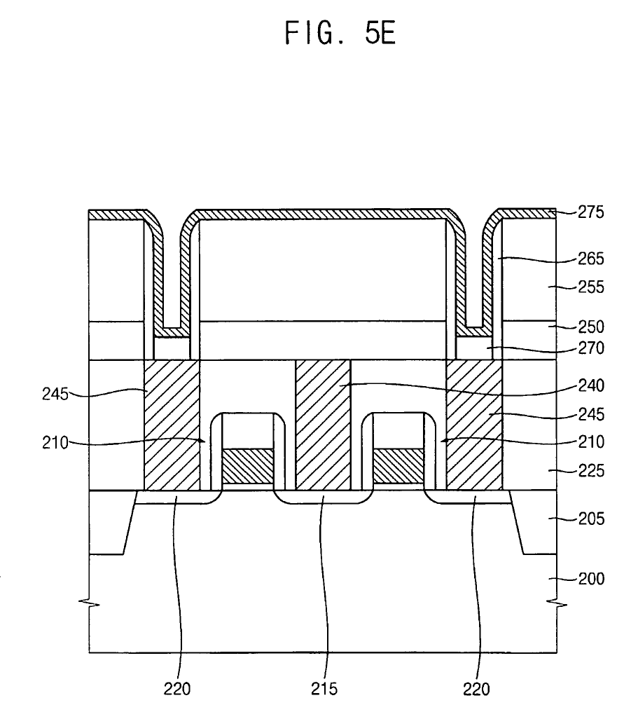

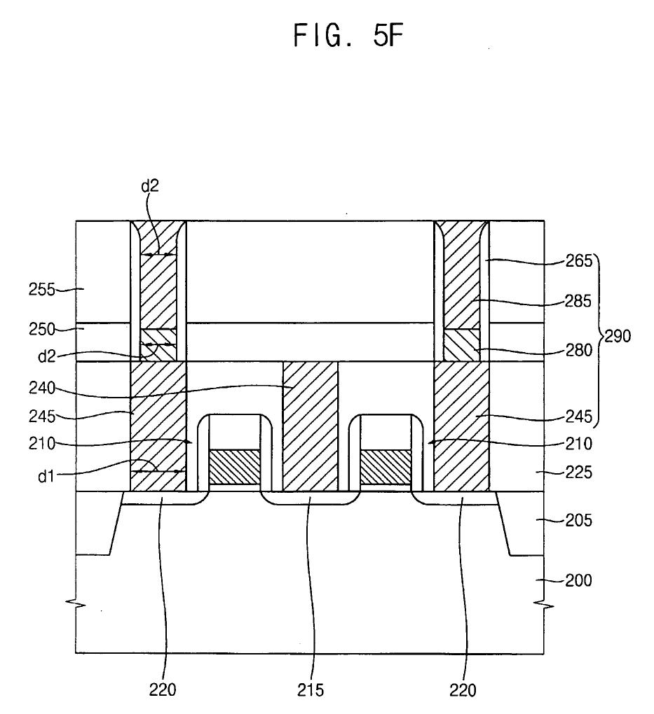

FIGS. 5A to 5F are diagrams illustrating cross-sectional views of a method of manufacturing a semiconductor device in accordance with example embodiments of the present invention.

Referring to FIG. SA, an isolation layer 205 may be formed on a substrate 200 by an isolation process (e.g., a shallow trench isolation (STI) process or a LOCOS process) to define an active region and/or a field region.

A gate oxidation layer having a smaller thickness may be formed on the substrate 200 by a thermal oxidation process or a chemical vapor deposition (CVD) process. The gate oxidation layer may be formed on the active region defined by the isolation layer 205.

A gate conductive layer and a gate mask layer may be successively formed on the gate oxidation layer. The gate conductive layer may be formed using polysilicon. The gate conductive layer may be patterned to form a gate conductive layer pattern 210b. The gate mask layer may he patterned to a gate mask pattern 210c. The gate mask layer may be formed using a material having an etching selectivity relative to an etching selectivity of a first insulation interlayer 225. For example, when the first insulation interlayer 225 is formed using polysilicon, the gate mask layer may be formed using a nitride (e.g., silicon nitride).

The gate mask layer, the gate conductive layer and/or the gate oxidation layer may be successively patterned by a photolithography. A gate oxidation layer pattern 210a, the gate conductive layer pattern 210b and/or the gate mask pattern 210c may be formed on the substrate 200. A gate spacer 210d may be formed on a sidewall of a resultant structure including the gate oxidation layer pattern 210a, the gate conductive layer pattern 210b and/or the gate mask pattern 210c. The gate spacer 210d may be formed using a nitride (e.g., silicon nitride). A gate structure 210 including the gate oxidation layer pattern 210a, the gate conductive layer pattern 210b, the gate mask pattern 210c and/or the gate spacer 210d may be formed on the substrate 200.

Impurities may be implanted on a surface portion of the substrate 200 exposed between the gate structures 210 by an ion implantation process. The gate structure 210 may be used as an ion implantation mask during the ion implantation process. A first contact region 215 and/or a second contact region 220 may be formed on the substrate 200 by a thermal treatment process after the ion implantation process. For example, the first contact region 215 and the second contact region 220 may correspond to source/drain regions. Transistors including the gate structures 210, the first contact region 210 and the second contact region 220 may be formed on the substrate 200.

In example embodiments of the present invention, first impurities having a lower concentration may be implanted on the surface portion of the substrate 200 exposed between the gate structures 210 prior to forming the gate spacer 210d. After forming the gate spacer 210d, more highly concentrated second impurities may be implanted in the substrate 200. The first contact region 215 and the second contact region including a lightly doped drain (LDD) structure may be formed on the substrate 200.

Referring to FIG. 5B, a first insulation interlayer 225, including an oxide, may be formed on the substrate 200, covering the transistors. The first insulation interlayer 225 may be formed by a CVD process, a PE-CVD process, an ALD process, a HDP-CVD process. etc. In addition, the first insulation interlayer 225 may be formed using an oxide (e.g., BPSG, PSG, PE-TEOS, USG, FOX, SOG, HDP-CVD oxide, etc.).

The first insulation interlayer 225 may be partially removed by a CMP process, an etch-back process or a combination process of CMP and etch-back to planarize a surface of the first insulation interlayer 225. The first insulation interlayer 225 may have a desired height from the gate structure 210.

In other example embodiments of the present invention, the first insulation interlayer 225 may be partially removed to expose the gate structure 210.

The first insulation interlayer 225 may be partially etched to form a first contact hole 230 and a second contact hole 235 wherein the first and the second contact regions 215 and 220 are located, respectively. The first contact region 215 and the second contact region 220 may be exposed by the first contact hole 230 and the second contact hole 235, respectively.

A first conductive layer may be formed on the first insulation interlayer 225 to fill the first and the second contact holes 230 and 235. In example embodiments of the present invention, the first conductive layer may be formed using polysilicon.

The first conductive layer may be partially removed by a CMP process, an etch-back process or a combination process of CMP and etch-back in order to expose the first insulation interlayer 225. A first pad 240 and a second pad 245 may be simultaneously formed in the first contact hole 230 and the second contact hole 235, respectively. The first pad 240 may contact the first contact region 215. The second pad 245 may contact the second contact region 220.

In other example embodiments of the present invention, when the first insulation interlayer 225 is removed to expose the gate structure 210, the first conductive layer also may be removed to expose the gate structure 210. The first pad 240 and the second pad 245 may be formed as self-alignment contacts (SAC).

Referring to FIG. 5C, a second insulation interlayer 250 may be formed on the first insulation interlayer 225 including the first and the second pads 240 and 245. The second insulation interlayer 250 may electrically insulate the first pad 240 with a bit line (not shown) formed during a subsequent process. The second insulation interlayer 250 may be formed using an oxide (e.g., BPSG, PSG, PE-TEOS, USG, FOX, SOG, HDP-CVD oxide, etc.). In example embodiments of the present invention, the second insulation interlayer 250 may be formed using an oxide substantially the same as the first insulation interlayer 225. In example embodiments of the present invention, the second insulation interlayer 250 may be formed using an oxide substantially different from the first insulation interlayer 225. The bit line including a bit line conductive layer pattern (not shown) and a bit line mask pattern (not shown) may be formed on the second insulation interlayer 250.

A third insulation interlayer 255 may be formed on the second insulation interlayer 250 to cover the bit line. The third insulation interlayer 255 may be formed using an oxide (e.g., BPSG, PSG, PE-TEOS, USG, FOX, SOG, HDP-CVD oxide, etc.). The third insulation interlayer 255 may be formed using an oxide substantially the same as the second insulation interlayer 250. In example embodiments of the present invention, third insulation interlayer 255 may be formed using the oxide substantially different from the second insulation interlayer 250.

The third insulation interlayer 255 may be partially removed by a CMP process, an etch-back process or a combination of CMP and etch-back to planarize a surface of the third insulation interlayer 255.

A photoresist pattern (not shown) may be formed on the third insulation interlayer 255. The third insulation interlayer 255 and the second insulation interlayer 250 may be successively etched using the photoresist pattern as an etching mask. An opening 260 exposing the second pad 245 may be formed. The opening 260 may be formed having a dimension substantially the same as an opening of the second pad 245. The opening 260 may be formed having a greater dimension than the second pad 245. In yet other example embodiments of the present invention, the opening 260 may be formed having a smaller dimension than the second pad 245.

Referring to FIG. 5D, an insulation layer may be formed on the second pad 245 and the third insulating interlayer 255. A dimension of the insulation layer may be formed thinner the dimension of the opening 260. The dimension of the insulation layer may be half of the dimension of the opening 260 in order not to fill the opening 260. The insulation layer may be anisotropically etched to form a spacer 265 on a sidewall of the opening 260.

The spacer 265 may be formed using a material having an etching selectivity relative to the third insulation interlayer 255. For example, the spacer. 265 may be formed using a nitride (e.g., silicon nitride).

A preliminary third pad 270 partially filling the opening 260 may be formed. The preliminary third pad 270 may be formed in order not to fill the opening 260.

In example embodiments of the present invention, the preliminary third pad 270 may be formed by a selective epitaxial growth (SEG) process using the second pad 245 exposed by the opening 260. The SEG process may be performed by a low pressure chemical vapor deposition (LPCVD) process, an ultra high vacuum chemical vapor deposition (UHVCVD) process, etc.

In example embodiments of the present invention, the preliminary third pad 270 may be formed by the SEG process using the LPCVD process. In the SEG process using the LPCVD process, a dichlorosilane (SiCl₂H₂) gas and a hydrogen chloride (HCl) gas may be used as a reactant gas. A hydrogen (H₂) gas may be used as a carrier gas.

In other example embodiments of the present invention, the preliminary third pad 270 may be formed by the SEG process using the UHVCVD process. In the SEG process using the UHVCVD process, a silane (SiH₄) gas, a disilane (Si₂H₆) gas or a dichlorosilane (SiCl₂H₂) gas may be used as a reactant gas. The UHVCVD process may be performed at a lower temperature relative to a temperature of the LPCVD process.

She preliminary third pad 270 may be formed by growing silicongermanium using the SEG process. An ion implantation process implanting impurities may be performed after forming a silicongermanium layer.

In the SEG method, the silicon layer or the silicongermanium layer may be formed on the third insulation interlayer 255 by an undesirable epitaxial growth. The silicon layer or the silicongermanium layer on the third insulation interlayer 255 may be removed such that the silicon layer or the silicongermanium layer on the second pad 245 remains. The silicon layer or the silicongermanium layer on the third insulation interlayer 255 may he removed by an anisotropic etching process. In the anisotropic etching process, the preliminary third pad 270 on the second pad 245 may also be removed such that a height of the preliminary third pad 270 is insufficient to form a metal silicide or a metal silicongermanium.

According to example embodiments of the present invention, the SEG process and the anisotropic etching process may be repeated at least once. As such, the'silicon layer or the silicongermanium layer may not be formed on the third insulation interlayer 255. The preliminary third pad 270 having a desired height may be formed on the second pad 245.

According to yet other example embodiments of the present invention, a cleaning process may be performed prior to forming the preliminary third pad 270. The cleaning process may remove a native oxide layer formed on a surface of the second pad 245 and any etching damage occurred during a formation of the opening 260. When the SEG process is performed after the cleaning process, the silicon layer or the silicongermanium layer may be more uniformly formed on the second pad 245. In example embodiments of the present invention, the cleaning process may include a wet cleaning process using an etching solution including hydrogen fluoride. In other example embodiments of the present invention, the cleaning process may include a dry etching process. The cleaning process may also include a hydrogen baking process. The cleaning process may include a plasma native oxide cleaning (PNC) process using a hydrogen plasma, a nitrogen plasma or a combination of hydrogen plasma and nitrogen plasma. An inert gas may be further used in the PNC process.

Referring to FIG. 5E, a metal layer 275 may be formed to cover the preliminary third pad 270 and the third insulation interlayer 255. The metal layer 275 may be formed using titanium, cobalt, aluminum, tungsten, nickel, etc. The metal layer 275 may he formed by a CVD process, a PVD process, an ALD process, etc. For example, the metal layer 275 may be formed by a CVD process using titanium. During a subsequent silicidation process, a thickness of the metal layer 275 may be controlled as the preliminary third pad 270 is consumed. The metal silicide layer or the metal silicongermanium layer may be formed by a silicidation reaction between the metal layer 275 and the preliminary third pad 270. The metal layer 275 may be formed having a desired thickness such that the second pad 245 is not penetrated by the metal silicide layer or the metal silicongermanium layer.

In example embodiments of the present invention, a barrier layer may be further formed on the metal layer 275. The barrier layer may retard, or prevent, the metal layer 275 from oxidizing natively during a thermal process for forming a metal silicide layer or a metal silicongermanium layer. The barrier layer may be formed using a metal nitride (e.g., titanium nitride, titanium aluminum nitride, etc.).

Referring to FIG. 5F, a first rapid thermal process may be performed to react the preliminary third pad 270 and the metal layer 275. The first rapid thermal process may be performed at a temperature of about 450° C. to about 650° C. A preliminary metal silicide layer or a preliminary metal silicongermanium layer may be formed. Because the third insulation interlayer 255 and the spacer 265 do not include silicon or silicongermanium, the third insulation interlayer 255 and the spacer 265 may not be reacted with the metal layer 275 during the first rapid thermal process. An unreacted metal layer 275 may be removed.

A second rapid thermal process may be carried out to form the preliminary metal silicide layer or the preliminary metal silicongermanium layer. The second rapid thermal process may be performed at a temperature of about 750° C. to about 950° C. The preliminary metal silicide layer or the preliminary metal silicongermanium layer may be transformed to a metal silicide layer or a metal silicongermanium layer, respectively, by the second rapid thermal process. A third pad 280 may be formed on the second pad 245. The third pad 280 may include a metal silicide or a metal silicongermanium.

According to example embodiments of the present invention, the preliminary third pad 270 may be reacted with the metal layer 275. Substantially all of the preliminary third pad 270, or a portion thereof, may be reacted with the metal layer 275. The third pad 280 may include only the metal silicide or the metal silicongermanium. In other example embodiments of the present invention, a first portion of the preliminary third pad 270 may be reacted with the metal layer 275. A second portion of the preliminary third pad 270 may not be reacted with the metal layer 275. The third pad 280 may further include a SEG layer formed from the second pad 245. Because the preliminary third pad 270 may be formed by the SEG process, the preliminary third pad 270 may have a sufficient height from the second pad 245. The metal silicide or the metal silicongermanium in the third pad 280 may not be formed in the second pad 245. The occurrence of excessive agglomeration due to the metal silicide or the metal silicongermanium may decrease.

A second conductive layer may be formed on the third pad 280 and the third insulation interlayer 255 in order to fill the opening 260. The second conductive layer may be formed using polysilicon, a metal, a conductive metal nitride, etc. The second conductive layer may be formed by a sputtering process, a CVD process, an ALD process, a PLD process, etc.

The second conductive layer may be partially removed by a CMP process, an etch-back process or a combination of CMP and etch-back to expose the third insulation interlayer 255, forming a fourth pad 285. A pad structure 290 including the second pad 245, the third pad 280, the fourth pad 285 and the spacer 265 may be formed. The second pad 245 may contact the contact regions on the substrate 200. The second pad 245 may include polysilicon. The third pad 280 may contact the second pad 245. The third pad 280 may include a metal silicide or a metal silicongermanium. In other example embodiments of the present invention, the third pad 280 may further include the SEG layer derived from the second pad 245. The fourth pad 285 may contact the third pad 280. The fourth pad 285 may include polysilicon, a metal, a conductive metal nitride, etc. The spacer 265 may be formed on a sidewall of the third pad 280 and the fourth pad 285. A bottom face of the spacer 265 may be connected to the second pad 245.

According to example embodiments of the present invention, in a formation of a metal silicide layer or a metal silicongermanium layer for decreasing contact resistance, a silicon layer or a silicon germanium layer may be formed by a selective epitaxial growth (SEG) process on a region on which the metal silicide layer or the metal silicongermanium layer is formed. The silicon layer or the silicon germanium layer may be formed by performing a silicidation reaction. As a result, the occurrence of excessive agglomeration due to the metal silicide or the metal silicongermanium may be retard, or prevented. The likelihood of an electrical short occurring between adjacent pads due to the agglomeration may decrease.

The foregoing is illustrative of the example embodiments of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to he included therein.

What is claimed is:

1. A pad structure comprising:
a first pad including silicon;
a second pad formed on the first pad, the second pad including a metal silicide or a metal silicongermanium; and
a third pad formed on the second pad.

2. The pad structure of claim 1, wherein the third pad includes a conductive material.

3. The pad structure of claim 1, wherein the second pad includes a selective epitaxial growth (SEG) layer derived from the first pad.

4. The pad structure of claim 3, wherein the metal silicide or the metal silicongermanium is formed by performing a silicidation process on the SEG layer.

5. The pad structure of claim 4, wherein the second pad includes at least one selected from the group consisting of titanium silicide, cobalt silicide, tungsten silicide, nickel silicide, titanium silicongermanium, cobalt silicongermanium, tungsten silicongermanium and nickel silicongermanium.

6. The pad structure of claim 1, further comprising a spacer, wherein the spacer is formed on sidewalls of the second pad and the third pad, and a bottom surface of the spacer is connected to the first pad.

7. The pad structure of claim 6, wherein the first pad has a first dimension d₁, the second pad and the third pad each have a second dimension d₂, further wherein the equation d₁>d₂ is satisfied.

8. A semiconductor device including the pad structure of claim 1.

9. The semiconductor device according to claim 8, further comprising:
a substrate including a contact region electrically connected to the first pad;
a first insulation interlayer formed on the substrate, wherein the first pad is formed in the first insulation interlayer; and
a second insulation interlayer formed on the first pad and the first insulation interlayer such that an opening is formed through the second insulation interlayer exposing the first pad,
wherein the second pad partial fills the opening, the third pad completely fills the opening.

10. The semiconductor device of claim 9, wherein the second pad includes a selective epitaxial growth (SEG) layer derived from the first pad.

11. The semiconductor device of claim 10, wherein the metal silicide or the metal silicongermanium is formed by performing a silicidation process on the SEG layer.

12. The semiconductor device of claim 9, wherein the second pad includes at least one selected from the group consisting of titanium silicide, cobalt silicide, tungsten silicide, nickel silicide, titanium silicongermanium, cobalt silicongermanium, tungsten silicongermanium and nickel silicongermanium.

13. The semiconductor device of claim 9, further comprising a spacer, the spacer is formed on sidewalls of the second pad and the third pad, and the spacer is formed on top of the first pad.

14. A method of forming a pad structure comprising:
forming a first pad including silicon;
forming a second pad on the first pad, the second pad including a metal silicide or a metal silicongermanium; and
forming a third pad on the second pad.

15. The method of claim 14, wherein forming the second pad comprises:
forming an insulation layer on the first pad;
etching the insulation layer such that an opening is formed through the insulation layer exposing the first pad;
forming a preliminary second pad on the first pad, the preliminary second pad partially filling the opening;
forming a metal layer on the preliminary second pad; and
performing a thermal treatment process on the preliminary second pad and the metal layer to form the second pad on the first pad.

16. The method of claim 15, wherein forming the preliminary second pad further includes forming a selective epitaxial growth (SEG) layer derived from the first pad by performing a SEG process.

17. The method of claim 16, further comprising removing the SEG layer formed on the insulation layer.

18. The method of claim 16, further comprising performing a cleaning process prior to performing the SEG process.

19. Tie method of claim 18, wherein the cleaning process is performed using a hydrogen plasma.

20. The method of claim 15, wherein the metal layer includes at least one selected from the group consisting of titanium, cobalt, tungsten and nickel.

21. The method of claim 5, wherein performing the thermal treatment process includes:
performing a first rapid thermal treatment process on the preliminary second pad and the metal layer to form a preliminary metal silicide layer or a preliminary metal silicongermanium layer;
removing an unreacted metal layer; and
performing a second rapid thermal treatment process on the preliminary metal silicide layer or the preliminary metal silicongermanium layer.

22. The method of claim 21, wherein the first rapid thermal treatment process is performed at a temperature of about 450° C. to about 650° C., and the second rapid thermal treatment process is performed at a temperature of about 750° C. to about 950° C.

23. The method of claim 14, further comprising forming a spacer on sidewalls of the second pad and the third pad.

24. A method of manufacturing a semiconductor device according to claim 14.

25. The method of claim 24, further comprising:
forming a contact region on a substrate, wherein the first pad electrically connects to the contact region;
forming a first insulation interlayer on the substrate, wherein the first pad including silicon is formed in the first insulation interlayer;
forming a second insulation interlayer on the first pad and the first insulation interlayer;
forming an opening exposing the first pad;
forming a preliminary second pad on the first pad, the preliminary second pad partially filling the opening;
forming a metal layer on the preliminary second pad and the second insulation interlayer; and
performing a thermal treatment process on the preliminary second pad and the metal layer to form the second pad, wherein the third pad fills the opening.

26. The method of claim 25, wherein the preliminary second pad further comprises a selective epitaxial growth (SEG) layer derived from the first pad by performing a SEG process.

27. The method of claim 26, further comprising removing the SEG layer.

28. The method of claim 26, further comprising performing a cleaning process prior to the SEG process.

29. The method of claim 28, wherein the cleaning process is performed using a hydrogen plasma.

30. The method of claim 25, wherein the metal layer includes at least one selected from the group consisting of titanium, cobalt, tungsten and nickel.

31. The method of claim 25, wherein performing the thermal treatment process includes:
performing a first rapid thermal treatment process on the preliminary second pad and the metal layer to form a preliminary metal silicide layer or a preliminary metal silicongermanium layer;
removing an unreacted metal layer; and
performing a second rapid thermal treatment process on the preliminary metal silicide layer or the preliminary metal silicongermanium layer.

32. The method of claim 31, wherein the first rapid thermal treatment process is performed at a temperature of about 450° C. to about 650° C., and the second rapid thermal treatment process is performed at a temperature of about 750° C. to about 950° C.

33. The method of claim 25, further comprising forming a spacer on sidewalls of the second pad and the third pad.
